(19) United States
(12) Patent Application Publication
(10) Pub. No.: US 2022/0172964 A1
(43) Pub. Date: Jun. 2, 2022

(54) SUBSTRATE DELIVERY METHOD AND SUBSTRATE DELIVERY DEVICE

(71) Applicant: TOKYO ELECTRON LIMITED, Tokyo (JP)

(72) Inventor: Tadashi OBIKANE, Yamanashi (JP)

(21) Appl. No.: 17/533,452

(22) Filed: Nov. 23, 2021

(30) Foreign Application Priority Data
Nov. 30, 2020 (JP) 2020-198968

(51) Int. Cl. H01L 21/677; H01L 21/68

(52) U.S. Cl. CPC H01L 21/677; H01L 21/68

(57) ABSTRACT

The present disclose relates to a substrate delivery method that uses a substrate delivery device including an elevating body for moving upward and downward a plurality of mounting parts, on which a transport container for a substrate is placed. The substrate delivery method of the present disclosure comprises loading and unloading the substrate in the transport container; temporarily suspending the loading and unloading for the transport container when the external transport mechanism tries to deliver a transport container to and from another mounting part; and positioning said other mounting part at the delivery height position and delivering the transport container to and from the external transport mechanism.

### CROSS-REFERENCE TO RELATED APPLICATIONS

This application claims priority to Japanese Patent Application No. 2020-198968 filed on Nov. 30, 2020, the entire contents of which are incorporated herein by reference.

### TECHNICAL FIELD

The present disclosure relates to a substrate delivery method and a substrate delivery device.

### BACKGROUND

In processing a substrate, for example, a semiconductor wafer (hereinafter referred to as a “wafer”), which is a substrate is accommodated in a closed transport container and is transported by an external transport mechanism of each substrate processing device. When the substrate processing device includes a load port in which the transport container is placed, the transport container is delivered between the external transport mechanism and the load port. Then, the wafer is taken out from the transport container by a transport arm provided in the substrate processing device and is loaded into a substrate processing part.

Japanese Patent Application Publication No. 2008-235845 describes a loading chamber in which a housing for accommodating a plurality of objects to be processed is placed and two load ports disposed apart from each other along a side surface are provided. Further, the loading chamber is disposed between the load ports and is provided with a transport device for transporting the object to be processed between the load ports and the processing chamber.

### SUMMARY

The present disclosure provides a technology for efficiently replacing a transport container while suppressing an increase in an installation area of a substrate delivery device.

In accordance with an aspect of the present disclosure, there is provided a substrate delivery method by using a substrate delivery device including an elevating body in which a plurality of mounting parts, on which a transport container accommodating a substrate is placed, are arranged vertically and the mounting parts are integrally moved upward and downward, and an elevating mechanism which moves the elevating body upward and downward and moves each of the mounting parts on which the transport container is placed upward and downward to a delivery height position at which the transport container is delivered to and from an external transport mechanism and a loading and unloading height position at which loading and unloading of the substrate is performed between the transport container and a substrate processing part via a transport port provided in the substrate processing part which processes the substrate. The method comprises: a step of loading and unloading the substrate in which one mounting part on which the transport container is placed is positioned at the loading and unloading height position, the substrate accommodated in the transport container is loaded into the substrate processing part to perform processing, and the processed substrate is returned to the transport container; a step of temporarily suspending the loading and unloading step for the transport container on said one mounting part when the external transport mechanism tries to deliver a transport container to and from other mounting part different from said one mounting part at the delivery height position, and said other mounting part is not able to be positioned at the delivery height position because of loading and unloading of the substrate with respect to the transport container placed on said one mounting part; a step of subsequently positioning said other mounting part at the delivery height position and delivering the transport container to and from the external transport mechanism; and a step of moving said one mounting part to the loading and unloading height position and resuming the loading and unloading step of remaining substrates in the transport container placed on said one mounting part after the transport container is delivered to said other mounting part.

### BRIEF DESCRIPTION OF THE DRAWINGS

FIG. 1 is a plan view of a probe device to which a load port according to the present disclosure is applied.

FIG. 2 is a longitudinally sectional side view showing a part of the probe device.

FIG. 3 is a longitudinally sectional side view of a load port according to the present disclosure.

FIG. 4 is a first front view of the load port.

FIG. 5 is a second front view of the load port.

FIG. 6 is a first longitudinally sectional side view showing opening and closing of an opening and closing door in the probe device.

FIG. 7 is a second longitudinally sectional side view showing opening and closing of the door in the probe device.

FIG. 8 is a first operation diagram of the load port according to the present disclosure.

FIG. 9 is a second operation diagram of the load port according to the present disclosure.

FIG. 10 is a third operation diagram of the load port according to the present disclosure.

FIG. 11 is a fourth operation diagram of the load port according to the present disclosure.

FIG. 12 is a fifth operation diagram of the load port according to the present disclosure.

FIG. 13 is a sixth operation diagram of the load port according to the present disclosure.

FIG. 14 is a seventh operation diagram of the load port according to the present disclosure.

FIG. 15 is an eighth operation diagram of a load port according to the present disclosure.

FIG. 16 is a ninth operation diagram of the load port according to the present disclosure.

FIG. 17 is a tenth operation diagram of the load port according to the present disclosure.

FIG. 18 is an eleventh operation diagram of the load port according to the present disclosure.

FIG. 19 is a twelfth operation diagram of the load port according to the present disclosure.

FIG. 20 is a thirteenth operation diagram of the load port according to the present disclosure.

FIGS. 21A through 21F are first operation diagrams of a load port according to another embodiment.

FIGS. 22A through 22F are second operation diagrams of the load port according to another embodiment.

### DETAILED DESCRIPTION

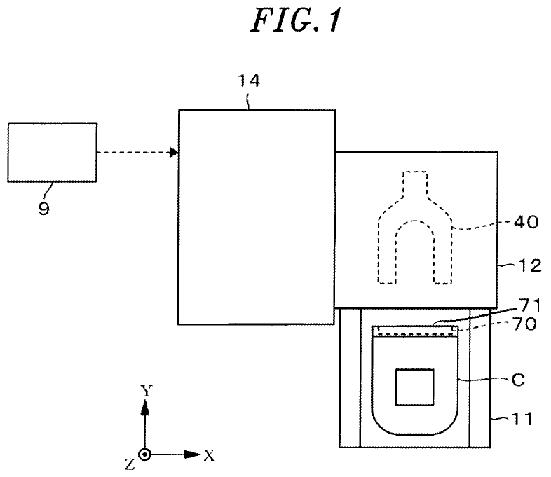

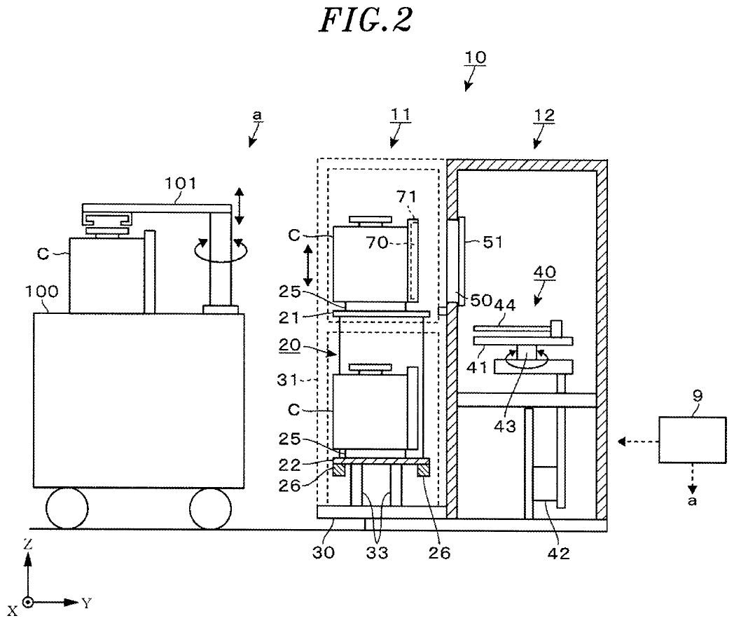

An embodiment in which a substrate delivery device according to the present disclosure is applied to a load port of a probe device will be described. The probe device 10 will be described with reference to FIGS. 1 and 2. As shown in FIG. 1, the probe device 10 includes a transport chamber 12 for transporting a wafer W, e.g., a substrate, and a load port 11, in which a transport container C is placed, is installed in front of the transport chamber 12. The transport container C contains, for example, the wafer W, e.g., 25 substrates. A take-out port 70 for the wafer W is provided on one side surface of the transport container C, and a lid 71 for closing the take-out port 70 is provided on the take-out port 70.

As shown in FIG. 2, one wafer transport port 50 which is a transport port for loading and unloading the wafer W is provided in the front wall of the transport chamber 12. An opening and closing door 51 which opens and closes together with the lid 71 of the transport container C is installed on the wafer transport port 50. The door 51 will be described later. Further, a transport arm 40 for transporting the wafer W is provided in the transport chamber 12. The transport arm 40 is configured to be able to move forward and backward with respect to a base 41 and includes a substrate support part 44 which horizontally supports the wafer W. The base 41 is rotatably configured by a rotating shaft 43 and is configured to be able to move up and down due to an elevating mechanism 42. A main body part 14 of the probe device is connected to the side of the transport chamber 12.

The main body part 14 examines electrical characteristics of a chip to be inspected, for example, by bringing a probe needle into electrical contact with an electrode pad of the chip to be inspected formed on the wafer W. The transport chamber 12 and the main body part 14 correspond to the substrate processing part.

During the processing of the wafer W by the probe device 10, the transport container C is delivered to the load port 11 from an external transport mechanism such as an automatic guided vehicle (AGV) 100. The wafers W accommodated in the transport container C are taken out one by one, transported through a route from the transport chamber 12 to the main body part 14, and a probe inspection is performed. The processed wafer W is transported through a reverse route in the probe device 10 and is returned to the transport container C.

Generally, in a wafer (W) processing device, for example, the external transport mechanism, such as AVG 100, transports the transport container C accommodating the wafer (W) to the device, and replaces the transport container C placed in the load port. Then, the wafer W is processed in order. Here, in order to improve processing efficiency of the processing device, it is preferable to keep processing of the wafer W in the ongoing transport container C as much as possible even after the replacement of the transport container C is initiated.

Therefore, for example, a method in which a plurality of load ports are arranged and installed in a horizontal direction, the transport container C is transported to each of the load ports, and the wafer W in the transport container C placed in the other load port is processed when the transport container C is replaced at one load port can be considered. However, this method has a problem that a footprint of the entire device increases as the number of the installed load ports increases. Further, when the transport container C is transported to a plurality of locations, teaching for aligning a transport position of the external transport mechanism becomes complicated.

Against this background, the probe device 10 according to the present disclosure includes the load port 11 capable of improving the processing efficiency of the probe device 10 while maintaining the low footprint of the device.

The load port 11 of the present disclosure will be described with reference to FIGS. 2 to 5. In the following description, for convenience, the transport chamber 12 side will be referred to as the front side, and the load port 11 side will be referred to as the rear side.

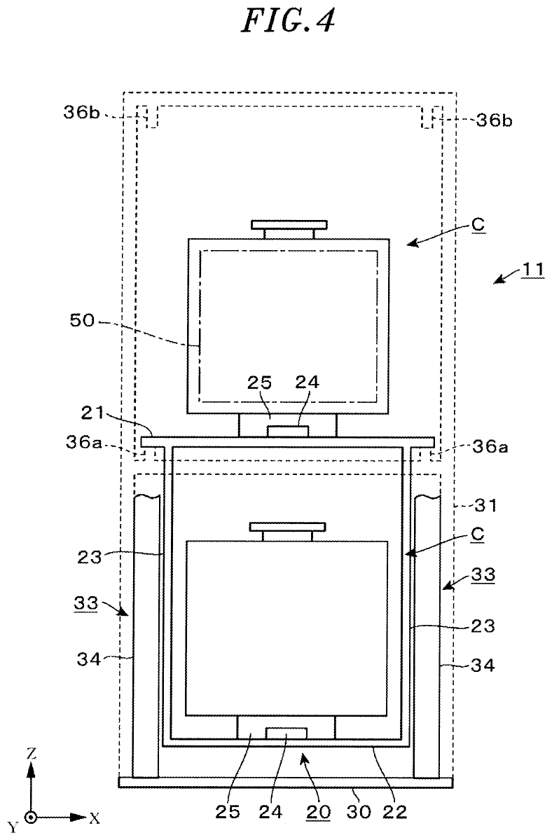

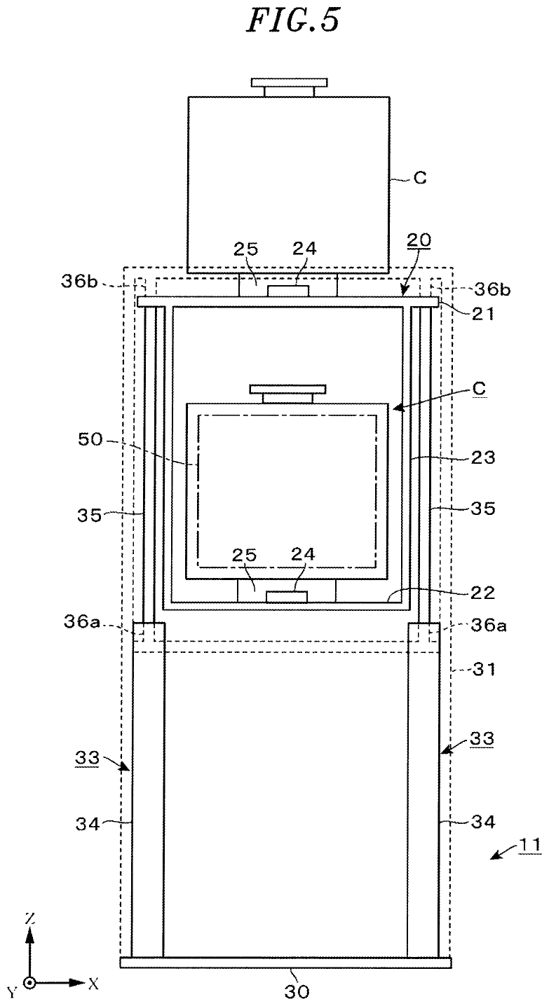

As shown in FIG. 2, the load port 11 has a configuration in which the elevating body 20 is disposed above the base 30. As shown in FIGS. 4 and 5, the elevating body 20 is configured as a housing in which a top plate 21 and a bottom plate 22 arranged at an interval in a vertical direction, and right and left side walls 23 which support the top plate 21 and the bottom plate 22 are included, and a front surface and a rear surface are open. Right and left peripheral edge portions of the top plate 21 protrude to the right and left further than the side wall 23.

As shown in FIGS. 2 to 5, stages 25 which are mounting parts on which the transport containers C are placed are provided on the upper surface side of the top plate 21 and the upper surface side of the bottom plate 22 of the elevating body 20. That is, two stages 25 can be disposed side by side in the vertical direction in the elevating body 20. A stage moving mechanism (not shown) with a driving part such as a motor or an air cylinder is provided in the stage 25. With such a stage moving mechanism, the stage 25 can perform an advance operation and a retraction operation along a rail 24 (not shown in FIG. 2) which extends in a forward and rearward direction. The stage 25 moves between a loading position in which the take-out port 70 of the transport container C is advanced to a position at which it is connected to the wafer transport port 50, and an unloading position in which the transport container C is delivered to and from the AGV 100 by the take-out port 70 retracting from the loading position.

Further, a frame 31 which surrounds the elevating body 20 is provided above the base 30. Further, as shown in FIGS. 4 and 5, on the left and right sides of the elevating body 20, a total of four air cylinders 33 which are elevating mechanisms extending upward from the base 30 are provided to be arranged in a row with two air cylinders 33 in each of the front and rear.

The air cylinder 33 includes a cylinder tube 34 and a piston rod 35 provided in the cylinder tube 34 and having a tip end protruding upward. The air cylinder 33 causes the piston rod 35 to protrude out of the cylinder tube 34 by supplying air into the cylinder tube 34. In this example, the tip end of the piston rod 35 is disposed to move upward. The tip end of the piston rod 35 is connected to a lower surface of a portion protruding from the side wall 23 on the top plate 21 side of the elevating body 20, the elevating body 20 is moved upward by moving the piston rod 35 upward, and the elevating body 20 is moved downward by moving the piston rod 35 downward.

Along with the upward and downward movement operation of the elevating body 20 described above, the stages 25 provided on the top plate 21 and the bottom plate 22 also integrally move upward and downward. Thus, the elevating body 20 can move each of the stages 25 on the top plate 21 side (the upper side) and the bottom plate 22 side (the lower side) to a height position at which the transport container C is delivered to and from the external transport mechanism (a delivery height position) and a height position at which the wafer W is loaded in and unloaded from the transport chamber 12 (a loading and unloading height position). In this example, the height position (the loading and unloading height position) at which the wafer W is loaded in and unloaded from the transport chamber 12 and the height position (the delivery height position) at which the transport container C is delivered to and from the AGV 100 are set to the same height. In the following explanation, the loading and unloading height position and the delivery height position in this example are also referred to as a reference height position.

FIG. 4 shows a state in which the transport container C placed on the stage 25 on the upper side is moved to the reference height position, and FIG. 5 shows a state in which the transport container C placed on the stage 25 on the lower side is moved to the reference height position.

Further, a restriction member 36a for aligning the stage 25 on the upper side with the reference height position when the elevating body 20 is moved downward is provided at a middle portion of the frame 31. The restriction member 36a comes into contact with the peripheral edge of the top plate 21 from the lower surface side to restrict the downward movement of the elevating body 20 (FIG. 4). Further, a restriction member 36b for aligning the stage 25 on the lower side with the reference height position when the elevating body 20 is moved upward is provided at an upper portion of the frame 31. The restriction member 36b comes into contact with the peripheral edge of the top plate 21 from the upper surface side to restrict the upward movement of the elevating body 20 (FIG. 5). The restriction members 36a and 36b are configured as shock absorbers which absorb an impact of a collision between the restriction members 36a and 36b and the top plate 21.

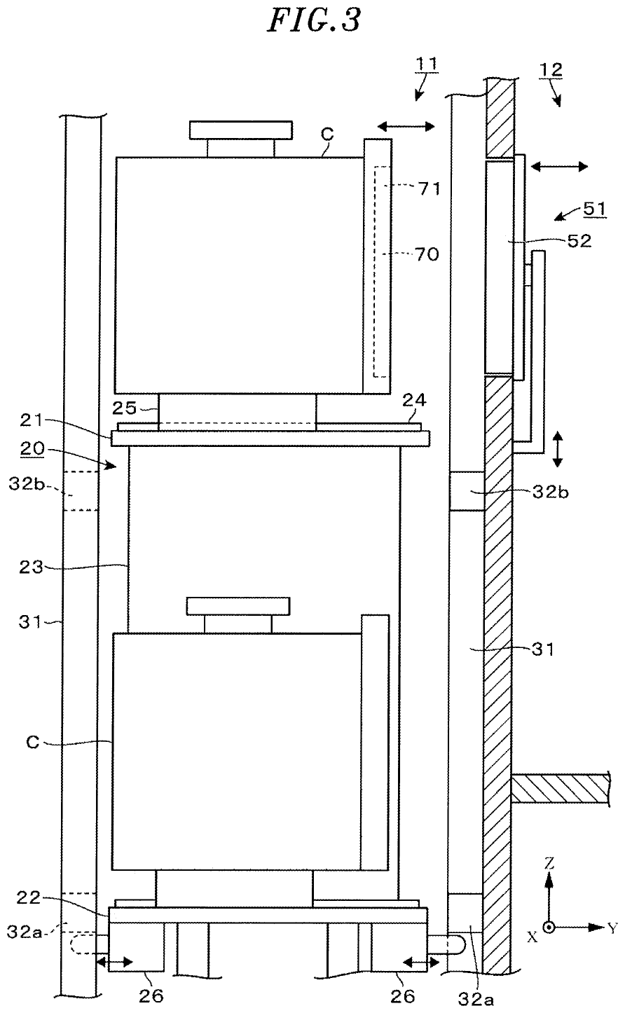

Further, as shown in FIGS. 2 and 3, stoppers 26 are provided at positions in front of and behind a lower surface of the bottom plate 22 of the elevating body 20. Each of these stoppers 26 has a structure in which it expands and contracts between a position at which it retracts below the bottom plate 22 and a position at which it protrudes in the forward and rearward direction from below the bottom plate 22. On the other hand, a locking and fixing portion 32a for locking and fixing the stopper 26 from the upper surface side in a state in which it protrudes from the bottom plate 22 when the stage 25 on the upper side is moved to the reference height position is provided on the lower portion side of the frame 31 (FIG. 3).

Further, a locking and fixing portion 32b for locking and fixing the stopper 26 from the lower surface side in a state in which it protrudes from the bottom plate 22 when the stage 25 on the lower side is moved to the reference height position is provided on the upper portion side of the frame 31. A state in which the stopper 26 is locked and fixed to the locking and fixing portion 32b is omitted from the drawing.

Then, in the upward and downward movement of the elevating body 20, when the stopper 26 is retracted below the bottom plate 22 and each of the stages 25 is positioned at the reference height, the stopper 26 is extended and locked and fixed to the locking and fixing portions 32a and 32b. Thus, the elevating body 20 is fixed at a predetermined height position, and it is possible to prevent the elevating body 20 from being displaced or falling due to air leakage of the air cylinder 33.

Subsequently, the door 51 will be described with reference to FIGS. 3, 6, and 7. The door 51 includes a lid holding part 52 which is formed in a plate shape to close the wafer transport port 50 of the transport chamber 12 and holds the lid 71 provided on the transport container C side.

A latch key (not shown) is provided on a surface of the lid holding part 52 which faces the transport container C, and the latch key is inserted into and removed from a key hole (not shown) of the lid 71.

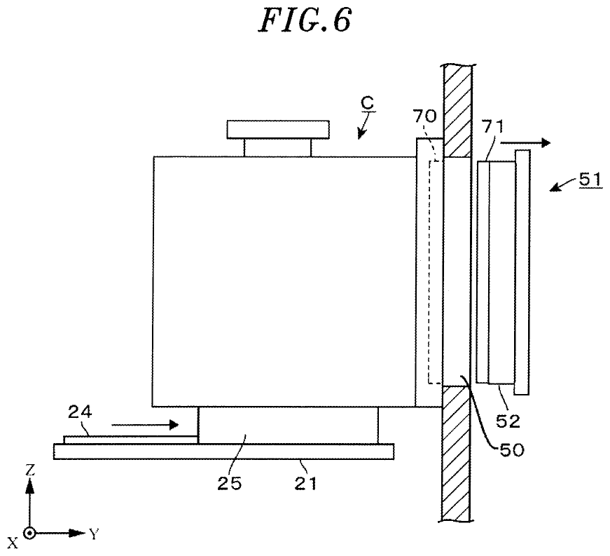

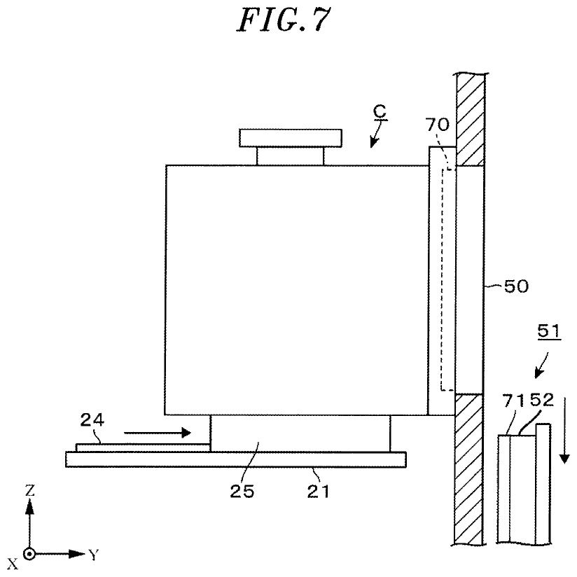

The lid holding part 52 removes the lid 71 from the transport container C, moves forward from a position at which the wafer transport port 50 is closed and opens the wafer transport port 50 (FIG. 6). After that, the door 51 is retracted downward by the door opening and closing mechanism 53 (FIG. 7).

Further, the take-out port of the transport container C and the wafer transport port 50 are connected to each other by advancing the transport container C in the unloading position and positioning it in the loading position. Regardless of whether the lid 71 is attached or detached, the transport container is moved to the loading position, and the take-out port of the transport container C and the wafer transport port 50 are connected to each other in a state in which they are aligned with each other.

Further, the connection is released by retracting the stage 25 from the state in which the take-out port 70 of the transport container C and the wafer transport port 50 are connected to each other.

The door 51 corresponds to a lid opening and closing mechanism, and the moving mechanism of the stage 25 corresponds to a connection mechanism for connecting the take-out port 70 of the transport container C to the wafer transport port 50.

Returning to FIGS. 1 and 2, the probe device 10 includes a control part 9. The control part 9 is configured as, for example, a computer, and has a data processing part including a program, a memory, and a CPU. The program incorporates instructions (each of steps) so that a control signal is sent from the control part 9 to each of parts of the probe device 10 and a probe inspection including the transport operation of the transport container C and the loading and unloading operation of the wafer W is proceeded. Further, the control part 9 transmits a call signal which requests the AGV 100 to recover and load the transport container C for recovery of the transport container C and subsequent load of the transport container C. The program is stored in a storage part such as a computer storage medium, for example, a flexible disk, a compact disc, a hard disk, or an magneto-optical (MO) disk, or the like and is installed in the control part 9.

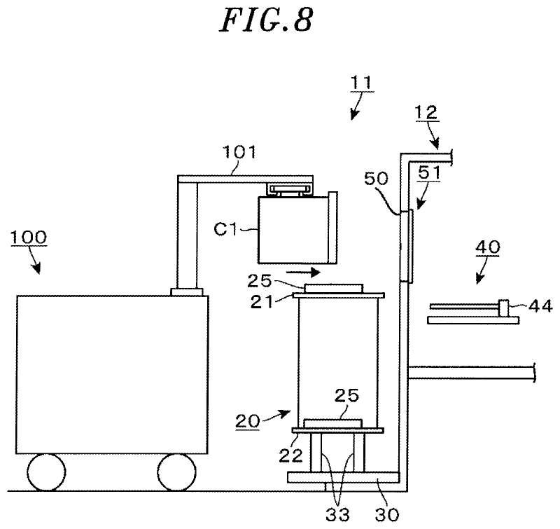

Subsequently, an operation of the load port 11 according to the embodiment of the present disclosure will be described. Hereinafter, FIGS. 8 to 20 show a state in which a dot pattern is applied to the transport container C in which the accommodated wafer W is being inspected by the probe device 10. In addition, a state in which a diagonal pattern is applied to the transport container C in which the inspection of all the wafers W is completed and the recovery is waited for is shown. Further, the transport container C in which the wafer W has not yet been loaded into the probe device 10 is shown in a white state without any pattern. In addition, reference numerals 1, 2, 3 and 4 are also written on the transport containers C (C1 to C4) in order from the transport container C to be inspected first by the probe device 10.

To briefly explain the AGV 100 which transports the transport container C, the AGV 100 is a vehicle body which holds the transport container C and transports it between devices provided in a semiconductor manufacturing factory. The AGV 100 includes a vehicle main body, and an arm 101 for delivering the transport container C between the stages 25 of the load port 11, and delivers the transport container C to and from the stages 25. As described, the delivery height position for delivering the transport container C to and from the AGV 100 is the same as the loading and unloading height position for loading and unloading the wafer W through the wafer transport port 50 (the reference height position). Further, the AGV 100 performs movement for recovering the transport container C in which the processed wafer W is accommodated and movement for transporting the subsequent transport container C to the probe device 10 based on the call signal transmitted from the probe device 10.

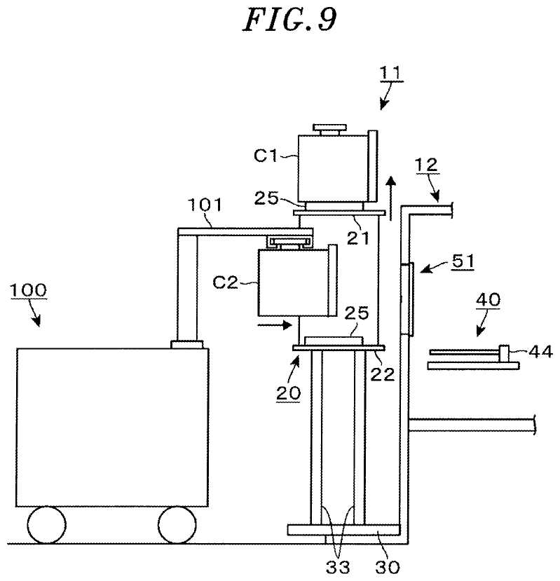

First, before the transport container C1 is received, for example, the elevating body 20 disposes the stage 25 on the upper side at the reference height position for receiving the transport container C1. Then, the transport container C1 transported by the AGV 100 is delivered to the stage 25 on the upper side at the unloading position (FIG. 8). Next, the elevating body 20 moves so that the stage 25 on the lower side is disposed at the reference height position for receiving the transport container C, and the transport container C2 transported by the AGV 100 is delivered to the stage 25 on the lower side (FIG. 9).

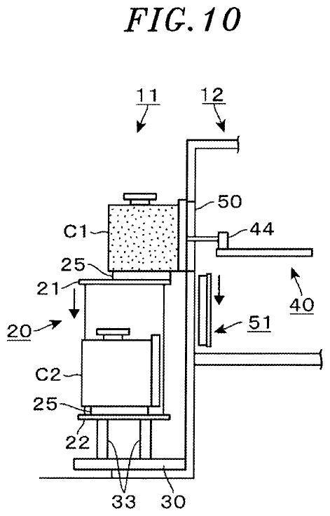

Subsequently, the elevating body 20 positions the stage 25 on the upper side at the reference height position. Next, the transport container C1 is advanced to move to the loading position, the take-out port 70 of the transport container C1 is connected to the wafer transport port 50, and the lid 71 of the transport container C1 opens (a step of connecting the take-out port to the transport port and opening the lid). Then, the substrate support part 44 of the transport arm 40 is brought into the transport container C1, the wafer W in the transport container C1 is taken out, and the wafer W is loaded into the main body part 14 of the probe device 10 to perform the inspection. Further, the wafer W for which the inspection is completed is returned to the transport container C1 (FIG. 10).

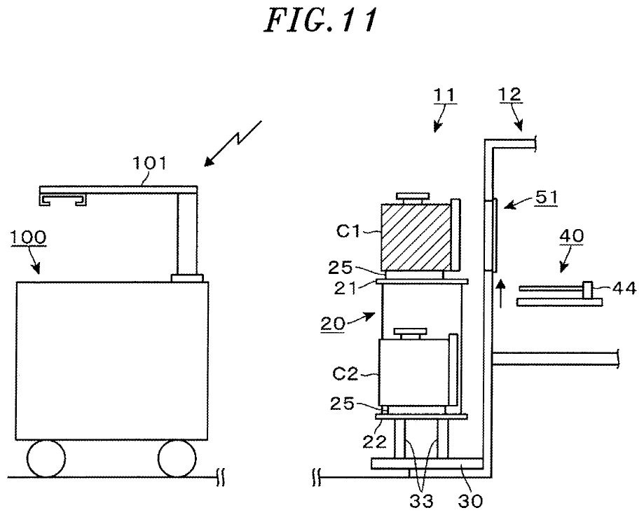

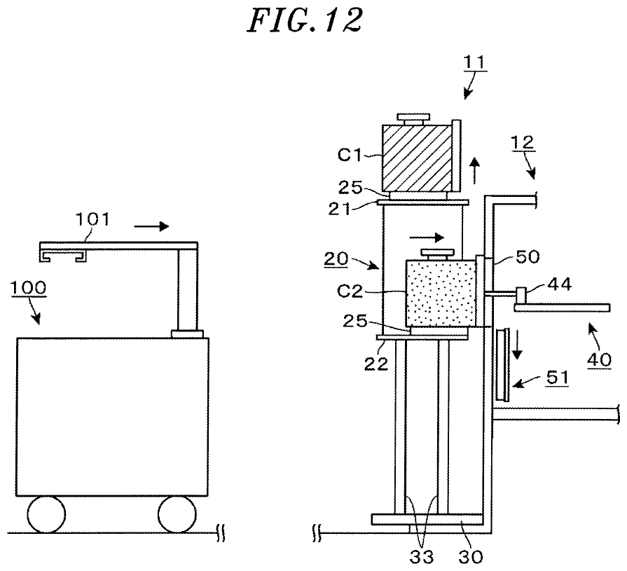

Further, when the inspection of the wafers W in the transport container C1 is completed and all the wafers W are returned to the transport container C1, the lid 71 of the transport container C1 is closed, and the transport container C1 is retracted from the loading position (a step of closing the lid and releasing the connection between the take-out port and the transport port). Furthermore, a call signal for the recovery of the transport container C1 is transmitted toward the AGV 100 (FIG. 11, a step of calling the external transport mechanism). The transmission of the call signal is performed before the loading and unloading of the wafer W accommodated in the transport container C2 which will be described with reference to FIG. 12 starts.

Then, after the loading and unloading of the wafer W with respect to the transport container C1 is completed, the stage 25 on the lower side is moved upward to the reference height position during a period until the AGV 100 arrives to receive the transport container C1. Next, as in the above-described transport container C1, the take-out port 70 and the wafer transport port 50 are connected to each other, and the lid 71 of the transport container C2 opens. Then, the wafer W in the transport container C2 is taken out by the transport arm 40 and is loaded into the probe device 10 to perform the inspection, and the wafer W for which the inspection is completed is returned to the transport container C2 (FIG. 12, a step of loading and unloading the substrate).

Here, at a time when the processing of the wafer W accommodated in the transport container C2 placed on the stage 25 on the lower side (corresponding to “one mounting part” in this case) is not completed, a case in which the AGV 100 recovers the transport container C1 which accommodates the wafer W which is processed is considered. In this case, since the stage 25 on the upper side (corresponding to “another mounting part” in this case) is disposed above the reference position, the transport container C1 cannot be delivered (FIG. 12).

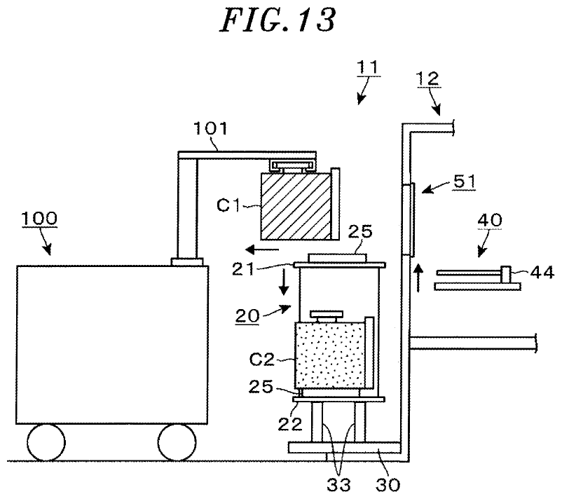

Therefore, the load port 11 of this example temporarily suspends the loading and unloading of the wafer W in the transport container C2 (temporarily suspends the inspection of the wafer W) at a timing when the AGV 100 arrives at the position at which the transport container C1 is recovered (a step of temporarily suspending the loading and unloading step). Further, the lid 71 of the transport container C2 is closed, and the transport container C2 is retracted to the unloading position. Next, the stage 25 on the upper side is moved downward to the reference height position, and the transport container C1 is recovered by the AGV 100 (FIG. 13, a step of delivering the transport container).

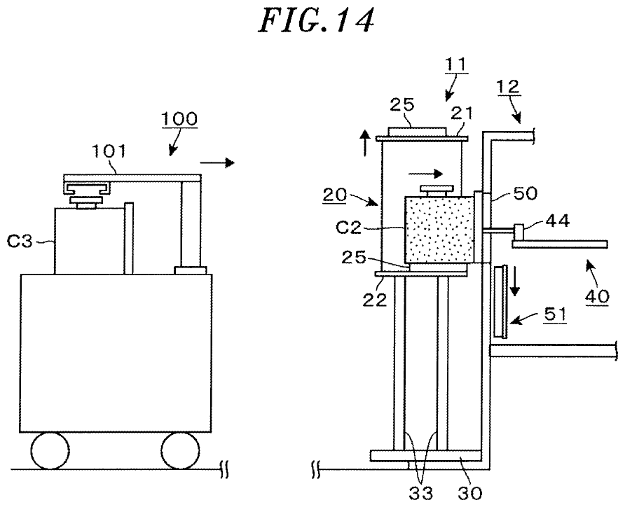

After the transport container C1 is recovered by the AGV 100, the inspection of the wafer W is resumed during a period until the AGV 100 which transports the subsequent transport container C3 in which the unprocessed wafer W is accommodated arrives at the probe device 10. That is, the stage 25 on the lower side is moved upward to the reference height position, and the lid 71 of the transport container C2 opens. The inspection of the wafer W accommodated in the temporarily suspended transport container C2 is resumed (FIG. 14, a step of resuming the loading and unloading step, and a step of loading and unloading the substrate).

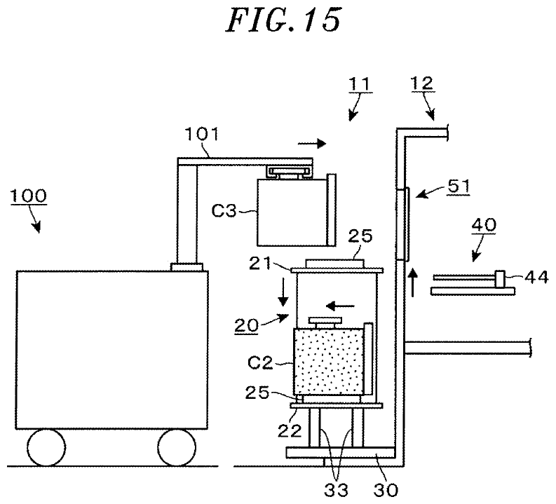

Therefore, at the timing when the AGV 100 which has transported the transport container C3 arrives at the position at which the transport container C3 is delivered, the stage 25 on the upper side (other mounting part) is disposed above the reference position as shown in FIG. 14. Therefore, the delivery of the transport container C1 cannot be performed. Therefore, here as well, the loading and unloading of the wafer W (the inspection of the wafer W) in the transport container C2 is temporarily suspended (a step of temporarily suspending the loading and unloading step). Further, the lid 71 of the transport container C2 is closed and retracted to the unloading position. Next, the stage 25 on the upper side is moved downward to the reference height position, and the transport container C3 is received by the AGV 100 (FIG. 15).

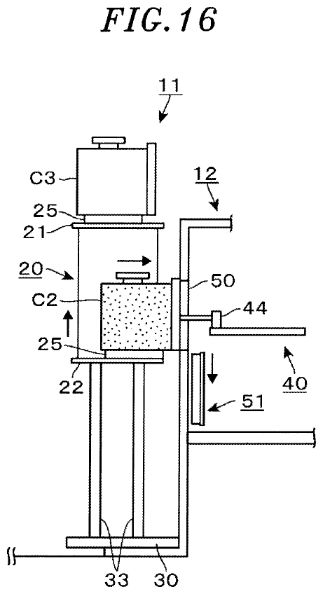

When the transport container C3 is delivered to the stage 25 on the upper side in this way, the stage 25 on the lower side is moved to the reference height position. Further, as described above, the transport container C2 is connected to the transport chamber 12, and the loading and unloading of the wafer W in the temporarily suspended transport container C2 is resumed (FIG. 16, a step of resuming the loading and unloading step, and a step of loading and unloading the substrate).

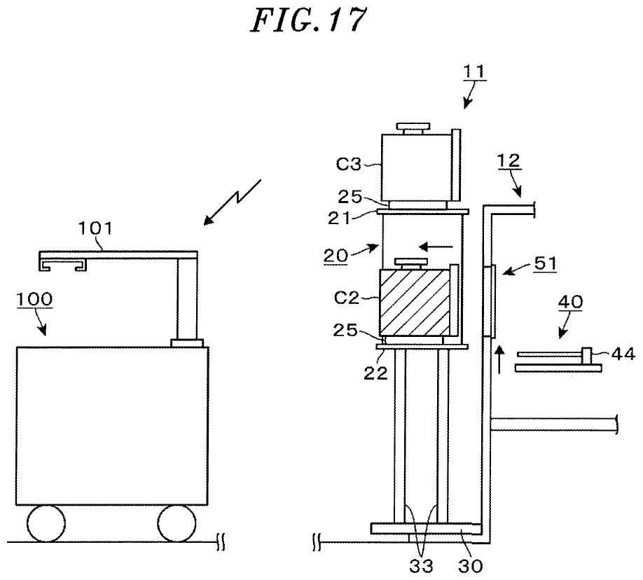

Then, when the inspection of the wafers W in the transport container C2 is completed and all the wafers W are returned to the transport container C2, the lid 71 of the transport container C2 is closed, and the transport container C2 is retracted to the unloading position. Further, the call signal is transmitted to the AGV 100 so as to recover the transport container C2 (FIG. 17, a step of calling the external transport mechanism).

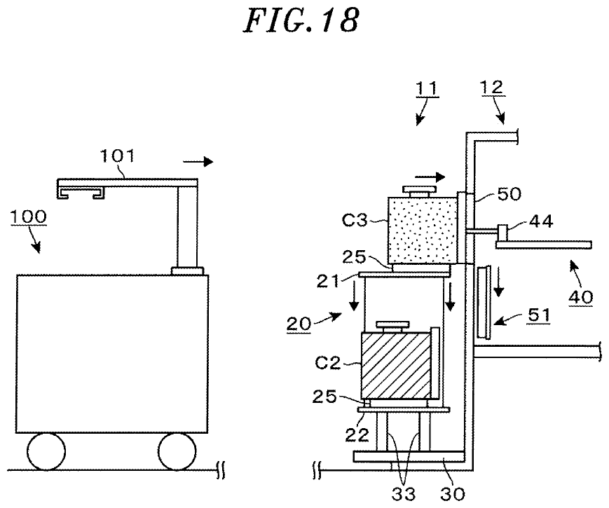

When the call signal is transmitted, the stage 25 on the upper side (here, corresponding to “one mounting part”) is moved to the reference height position while the AGV 100 is moving to receive the transport container C2. Then, the transport container C3 is advanced to the loading position to connect the take-out port 70 to the wafer transport port 50, and the lid 71 of the transport container C3 is removed. Further, the wafer W in the transport container C3 is taken out by the transport arm 40 and is loaded into the probe device, the inspection of the wafer W is performed, and the wafer W for which the inspection is completed is returned to the transport container C3 (FIG. 18, the step of loading and unloading the substrate).

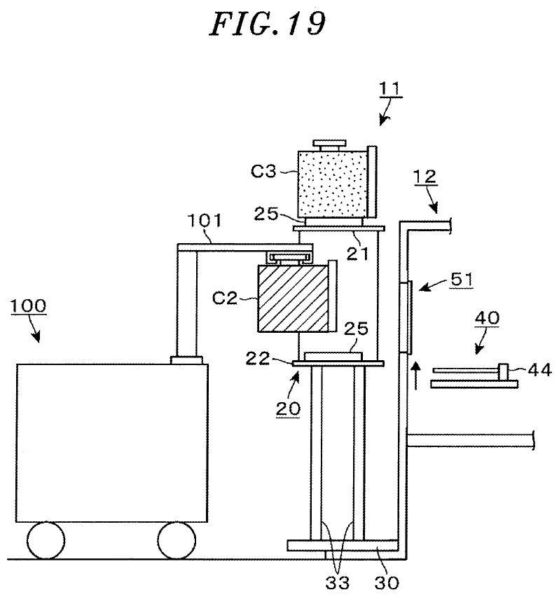

Then, the inspection of the wafer W in the transport container C3 is temporarily suspended at the timing when the AGV 100 for recovering the transport container C2 arrives at the recovery position (the step of temporarily suspending the loading and unloading step). Further, the lid 71 of the transport container C3 is closed and retracted to the unloading position. Next, the stage 25 on the lower side (corresponding to “another mounting part” in this case) is moved upward to the reference height position, and the transport container C2 is recovered by the AGV 100 (FIG. 19, the step of delivering the transport container).

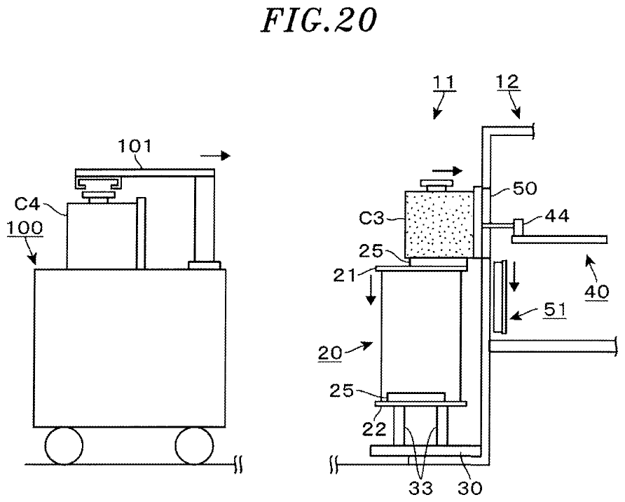

Subsequently, after the AGV 100 recovers the transport container C2, the inspection of the wafer W is resumed during a period until the AGV 100 for transporting the subsequent transport container C4 arrives at the probe device 10. That is, the stage 25 on the upper side is moved downward to the reference height position, and the inspection of the wafer W is resumed (FIG. 20, the step of resuming the loading and unloading process, and the step of loading and unloading the substrate).

After that, the operation of replacing the transport containers C1 to C4 in order is repeated to perform the inspection of the wafer W based on the operations described with reference to FIGS. 9 to 20.

In the above-described embodiment, the elevating body 20 in which the stages 25 on which the transport container C is placed are disposed in two upper and lower stages is provided in the load port 11. Then, the transport container C placed on each of the stages 25 can be positioned at the loading and unloading height position for loading the wafer W into the probe device 10 by moving the elevating body 20 upward and downward. It is possible to prevent the increase in the installation area of the load port 11 by vertically disposing the stages 25 on which the transport container C is placed.

Then, the probe inspection of the wafer W in the transport container C (hereinafter, also referred to as “one transport container C”) placed on one stage 25 is completed. Subsequently, the transport container C (hereinafter, also referred to as “another transport container C”) placed on the other stage 25 is moved to the loading and unloading height position until the AGV 100 for recovering the transport container C arrives at the recovery position, and the probe inspection of the wafer W is performed. With such a configuration, the inspection of the wafer W in the other transport container C can be performed while the AGV 100 is heading for the recovery of the transport container C.

Further, when the AGV 100 for recovering one transport container C arrives, the processing of the wafer W in the other transport container C is temporarily suspended, and then the recovery of the one transport container C is performed. Further, after the one transport container C is recovered, the wafer W in the one transport container C in which the processing is temporarily suspended is performed until the AGV 100 which transports the subsequent new transport container C in which the unprocessed wafer W is accommodated arrives at the probe device. With such a configuration, while the AGV 100 for performing the loading of the new transport container C is moving, the probe inspection of the wafer W accommodated in the other transport container C can be performed. Due to the above-described action, the transport operation of the transport container C having the structure in which the plurality of stages 25 are arranged vertically can increase the processing efficiency of the wafer W and then improve a throughput of the probe device 10.

Here, the loading and unloading height position at which the loading and unloading of the wafer W in the transport container C is performed and the delivery height position at which the transport container C is delivered to and from the AGV 100 may be set at different height positions.

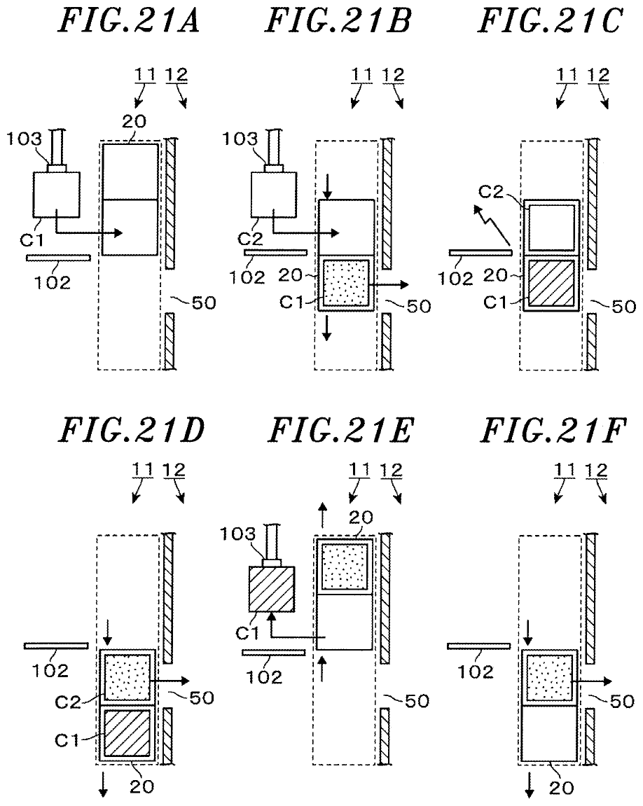

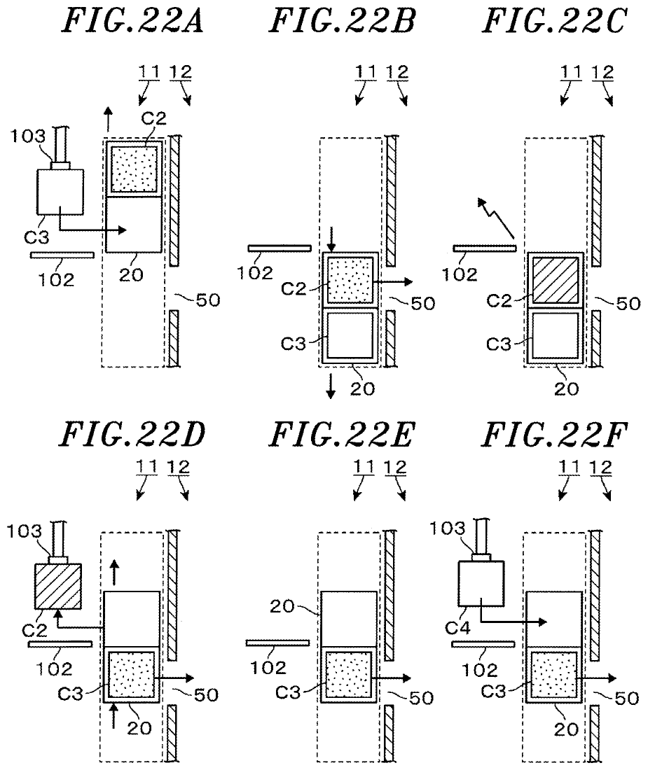

For example, FIGS. 21A to 21F and FIGS. 22A to 22F show an example in which the transport container C is delivered using an overhead hoist transport (OHT) 103 which is an external transport mechanism.

In this example, when the transport container C on the lower side is at the height position (the loading and unloading height position) for performing the loading and unloading of the wafer W, the transport container C on the upper side is positioned at a height position (the delivery height position) at which the transport container C is delivered.

Additionally, in this example, a mounting part 102 for placing the transport container C which is moved downward from the OHT 103 is provided, and the transport container C placed on the mounting part is delivered to the stage 25 positioned at a height position at which the transport container C is delivered by, for example, the transport arm (not shown).

In this example, as shown in FIGS. 21A to 21C, first, for example, the transport container C1 is delivered to the stage 25 on the lower side, and the transport container C2 is delivered to the stage 25 on the upper side. Then, the processing of the transport container C1 on the lower side is completed. Further, while the processing of the transport container C2 on the upper side is performed continuously, the transport container C1 on the lower side is delivered to and from the OHT 103. In this case, it is necessary to temporarily suspend the processing of the transport container C2 on the upper side (operations of FIGS. 21D to 21F).

On the other hand, as shown in FIGS. 22A to 22C, a new transport container C3 is delivered to the lower side, and the processing of the transport container C2 on the upper side is completed. Then, while the processing of the transport container C3 on the lower side is performed, the transport container C2 on the upper side is delivered to and from the OHT 103. In this case, the delivery of the processing container on the upper side can be performed simultaneously without temporarily suspending the processing of the transport container C3 on the lower side (the operations in FIGS. 22D to F). In the operations in FIGS. 21A and B, when the stage 25 on the upper side is at a height position for delivering the transport container C, the transport container C1 on the lower side is at the height position for loading and unloading the wafer W. Therefore, the processing of the transport container C1 can be performed while the delivery of the transport container C2 is performed.

In addition, the stage 25 is configured so that it can be slid to a position at which it protrudes to behind the top plate 21 and the bottom plate 22, and the transport container C may be delivered between the OHT 103 and the stage 25 positioned behind the top plate 21 and the bottom plate 22.

Further, the elevating body 20 may have a configuration in which three or more stages 25 are disposed vertically. Further, the load port 11 according to the present disclosure is not limited to the probe device 10, and may be used for a substrate processing device such as a film forming device and an etching device.

It should be considered that the embodiments disclosed this time are exemplary in all respects and should be considered as being not restrictive. The above embodiment may be omitted, replaced, or modified in various forms without departing from the scope of the appended claims and the gist thereof.

What is claimed is:

1. A substrate delivery method by using a substrate delivery device including an elevating body in which a plurality of mounting parts, on which a transport container accommodating a substrate is placed, are arranged vertically and the mounting parts are integrally moved upward and downward, and an elevating mechanism which moves the elevating body upward and downward and moves each of the mounting parts on which the transport container is placed upward and downward to a delivery height position at which the transport container is delivered to and from an external transport mechanism and a loading and unloading height position at which loading and unloading of the substrate is performed between the transport container and a substrate processing part via a transport port provided in the substrate processing part which processes the substrate,
wherein the method comprising:
a step of loading and unloading the substrate in which one mounting part on which the transport container is placed is positioned at the loading and unloading height position, the substrate accommodated in the transport container is loaded into the substrate processing part to perform processing, and the processed substrate is returned to the transport container;
a step of temporarily suspending the loading and unloading step for the transport container on said one mounting part when the external transport mechanism tries to deliver a transport container to and from other mounting part different from said one mounting part at the delivery height position, and said other mounting part is not able to be positioned at the delivery height position because of loading and unloading of the substrate with respect to the transport container placed on said one mounting part;
a step of subsequently positioning said other mounting part at the delivery height position and delivering the transport container to and from the external transport mechanism; and
a step of moving said one mounting part to the loading and unloading height position and resuming the loading and unloading step of remaining substrates in the transport container placed on said one mounting part after the transport container is delivered to said other mounting part.

2. The substrate delivery method of claim 1, wherein the delivery height position and the loading and unloading height position are the same height position.

3. The substrate delivery method of claim 1, wherein, in the step of delivering the transport container to and from the external transport mechanism, the transport container accommodating the substrate for which the processing is completed is delivered to the external transport mechanism.

4. The substrate delivery method of claim 3, wherein the step of loading and unloading the substrate with respect to the transport container placed on said one mounting part is performed after the loading and unloading of the substrate with respect to the transport container placed on said other mounting part is completed until the external transport mechanism arrives at a position at which the transport container is delivered to and from the delivery height position.

5. The substrate delivery method of claim 3, further comprising a step of calling the external transport mechanism to perform the step of delivering the transport container placed on other mounting part after the loading and unloading of the substrate with respect to the transport container placed on said other mounting part is completed.

6. The substrate delivery method of claim 5, wherein the step of calling the external transport mechanism is performed before the step of loading and unloading the substrate with respect to the transport container placed on said one mounting part is performed.

7. The substrate delivery method of claim 1, wherein the step of loading and unloading the substrate with respect to the transport container placed on said one mounting part is performed after the transport container accommodating the substrate for which the processing is completed is delivered from said other mounting part to the external transport mechanism until the external transport mechanism arrives at the position at which the transport container is delivered to and from the delivery height position.

8. The substrate delivery method of claim 1,
wherein, when the transport container includes a lid which closes a take-out port for the substrate, and
wherein the substrate delivery device includes a lid opening and closing mechanism which opens and closes the lid, and a connection mechanism which is positioned at a height position at which the substrate is delivered to and from the substrate processing part, and attaches and detaches the take-out port of the transport container with the lid opened and the transport port, and
the substrate delivery method further includes:
a step of performing connection between the take-out port of the transport container with the lid opened and the transport port by the connection mechanism, and opening of the lid of the transport container by the lid opening and closing mechanism while the substrate is loaded and unloaded, and
a step of closing the lid of the transport container by the lid opening and closing mechanism and releasing the connection between the take-out port of the transport container and the transport port by the connection mechanism while the substrate is not loaded and unloaded.

9. A substrate delivery device comprising:
an elevating body in which a plurality of mounting parts on which a transport container accommodating a substrate is placed are arranged in a vertical direction and the mounting parts are integrally moved upward and downward;
an elevating mechanism which moves the elevating body upward and downward and moves each of the mounting parts on which the transport container is placed upward and downward to a delivery height position at which the transport container is delivered to and from an external transport mechanism and a loading and unloading height position at which loading and unloading of the substrate is performed between the transport container and a substrate processing part via a transport port provided in the substrate processing part which processes the substrate; and
a control part,
wherein the control part is configured to control the substrate delivery device to repeats:
a step of positioning one mounting part on which the transport container is placed at the loading and unloading height position, loading the substrate accommodated in the transport container into the substrate processing part to perform processing, and loading and unloading the substrate to return the processed substrate to the transport container,
a step of temporarily suspending the loading and unloading step when the external transport mechanism tries to deliver the transport container to and from other mounting part different from said one mounting part at the delivery height position, and said other mounting part is not able to be positioned at the delivery height position because of loading and unloading of the substrate with respect to the transport container placed on said one mounting part,
a step of subsequently positioning said other mounting part at the delivery height position and delivering the transport container to and from the external transport mechanism, and
a step of moving said one mounting part to the loading and unloading height position and resuming the loading and unloading step of the remaining substrates in the transport container placed on said one mounting part after the step of delivering the transport container to said other mounting part is performed.

10. The substrate delivery device of claim 9, wherein the delivery height position and the loading and unloading height position are the same height position.

11. The substrate delivery device of claim 9, wherein, in the step of delivering the transport container to and from the external transport mechanism, the control part causes delivery of the transport container accommodating the substrate for which the processing is completed to the external transport mechanism.

12. The substrate delivery device of claim 11, wherein the step of loading and unloading the substrate with respect to the transport container placed on said one mounting part is performed after the loading and unloading of the substrate with respect to the transport container placed on said other mounting part is completed until the external transport mechanism arrives at a position at which the transport container is delivered to and from the delivery height position.

13. The substrate delivery device of claim 11, wherein the control part performs a step of calling the external transport mechanism to perform the step of delivering the transport container placed on other mounting part after the loading and unloading of the substrate with respect to the transport container placed on said other mounting part is completed.

14. The substrate delivery device of claim 13, wherein the step of calling the external transport mechanism is performed before the step of loading and unloading the substrate with respect to the transport container placed on said one mounting part is performed.

15. The substrate delivery device of claim 9, wherein the step of loading and unloading the substrate with respect to the transport container placed on said one mounting part is performed after the transport container accommodating the substrate for which the processing is completed is delivered from said other mounting part to the external transport mechanism until the external transport mechanism arrives at the position at which the transport container is delivered to and from the delivery height position.

16. The substrate delivery device of claim 9, wherein when the transport container includes a lid which closes a take-out port for the substrate,
the substrate delivery device includes a lid opening and closing mechanism which opens and closes the lid, and a connection mechanism which is positioned at a height position at which the substrate is delivered to and from the substrate processing part, and attaches and detaches the take-out port of the transport container with the lid opened and the transport port,
the control part is configured to control a step of performing connection between the take-out port of the transport container with the lid opened and the transport port by the connection mechanism, and opening of the lid of the transport container by the lid opening and closing mechanism during a period while the substrate is loaded and unloaded, and a step of performing closing of the lid of the transport container by the lid opening and closing mechanism and releasing of the connection between the take-out port of the transport container and the transport port by the connection mechanism during a period while the substrate is not loaded and unloaded.
